(19) United States
(12) Patent Application Publication
(10) Pub. No.: US 2009/0096096 A1
(43) Pub. Date: Apr. 16, 2009

(54) SEMICONDUCTOR DEVICE AND CIRCUIT DEVICE HAVING THE SAME MOUNTED THEREON

(75) Inventor: Taizo INOUE, Takasaki-shi (JP)

Correspondence Address: K.A. PATENTS, 7613 East 90th Street, KANSASS CITY, MO, 64138, US

(73) Assignee: TAIYO YUDEN CO., LTD., Tokyo (JP)

(21) Appl. No.: 12/234,655

(22) Filed: Sep. 20, 2008

(30) Foreign Application Priority Data
Sep. 25, 2007 (JP) 2007-247032

(51) Int. Cl. H01L 23/498

(52) U.S. Cl. 257/737; 257/E23.068

(57) ABSTRACT

A semiconductor device has a semiconductor chip, terminals formed at a prescribed terminal pitch on the bottom side of the semiconductor chip, and columnar post electrodes formed on the terminals. The post electrodes are formed of two different metals, the side bonded with the terminals is constituted by first metallic portions while the side on which solder bumps is formed are constituted by second metallic portions. A dimension in the width direction of the first metallic portions is formed smaller than a dimension in the width direction of the second metallic portions.

### BACKGROUND OF THE INVENTION

1. Field of the Invention

The present invention relates to a semiconductor device mounted on a wiring substrate, and a circuit device having the semiconductor device mounted thereon.

2. Description of the Related Art

Circuit devices such as wireless modules and power-supply modules mounted on electronic devices are formed by mounting semiconductor devices and other passive components of integrated circuits (ICs) on ceramic wiring substrates or resin printed wiring substrates. In recent years, miniaturization of electronic devices has been advancing, and miniaturization of circuit devices is also demanded. Since the mounting area taken up by semiconductor devices in a circuit device is comparatively large, semiconductor device mounting is performed using a chip flip mounting technique to reduce this mounted area.

Flip chip mounting is a process in which, as shown in FIG. 13, a semiconductor device 12 having bumps 17 formed directly on terminals 13 provided at a terminal pitch P1 on the bottom side (a side facing a wiring substrate 14) of a semiconductor chip 12a, or, on columnar electrodes (post electrodes) formed on the terminals, is mounted on the wiring substrate 14 by bonding the bumps 17 to lands 15 (conductors that bond with terminal electrodes of electronic components) on the wiring substrate 14.

The wiring substrate 14 having mounted thereon the semiconductor device 12 undergoes stress caused by a difference in thermal expansion coefficient between the semiconductor chip 12a and the wiring substrate 14. The wiring substrate 14 also undergoes mechanical stresses such as bending and flexing. Cracks sometimes occur when these stresses are focused on the bumps 17 or post electrodes 16. An underfill technique of filling in a space formed between the semiconductor device and the wiring substrate with a resin, as disclosed in Japanese Unexamined Patent Application Publication No. 2002-313993, is carried out for the purpose of mitigating these kinds of stress. This kind of underfill is normally filled in the following manner. First a hardening resin such as epoxy resin or the like is applied around the semiconductor device mounted on the wiring substrate. At this time, the hardening resin is drawn into the space in between the semiconductor device and the wiring substrate passing through spaces in between the bumps or post electrodes. Then the filled resin is hardened. In this way, the underfill is filled into the space.

Recently, in the design of semiconductors, the miniaturization of semiconductor devices has been advancing. As a result, the size of semiconductor chips is decreasing, and there is a trend of the pitch P1, shown in FIG. 13, of terminals becoming increasingly narrow. When the pitch of terminals becomes increasingly narrow such as in the case of the pitch P2, shown in FIG. 14, of terminals, a distance PLX, shown in FIG. 13, between bumps or post electrodes becomes narrow as in the case of a distance PLY, shown in FIG. 14, between bumps or post electrodes, and because of this, it becomes difficult for the hardening resin to be drawn into the space in between a semiconductor device 22 and a wiring substrate 24. As a result, non-underfilled portions of space in between the semiconductor device 22 and the wiring substrate 24 have occurred.

### SUMMARY OF THE INVENTION

As a solution to this type of problem, embodiments of the present invention provide a semiconductor device in which there are no non-underfilled portions, and also provide a circuit device that is able to prevent cracks from occurring in the bumps and post electrodes due to stress by using this semiconductor device.

In an aspect, a semiconductor device is proposed as a first solving embodiment a semiconductor chip, a plurality of terminals provided in a row on the bottom side of the semiconductor chip, post electrodes formed of columnar metal and bonded to first end portions of the terminals, and solder bumps formed on second end portions of the post electrodes, in which the post electrodes include first metallic portions being bonded to the terminals, and second metallic portions being bonded to the solder bumps, and the dimension of the first metallic portions in the width direction is smaller than the dimension of the second metallic portions in the width direction.

According to the above mentioned first solving embodiment, since the distance between adjacent post electrodes of the semiconductor device is larger than the pitch of terminals it becomes easier for the underfill to enter therebetween. As a result, even if the pitch of terminals is narrow due to miniaturization of the semiconductor device, it becomes easier for underfill to be filled into the space in between the semiconductor device and the wiring substrate, making it possible to have no non-underfilled portions. Furthermore, since the second metallic portions bonded to the wiring substrate have a larger dimension in the width direction than the first metallic portions, it is possible to ensure a large area for bonding to lands. As a result, a sufficient bonding strength can be attained.

Also, in an aspect of the present invention, a semiconductor device in which the length of the first metallic portions are larger than the length of the second metallic portion is proposed as a second solving embodiment in addition to the first solving embodiment. According to this second solving embodiment, the first metallic portions are larger and the distance in between post electrodes is larger than the pitch of terminals of the semiconductor device. According to this, it is possible to ensure a large portion into which it is easy for underfill to enter therebetween.

A circuit device is also proposed that has a semiconductor device as a third solving embodiment which is flip-chip-mounted on a wiring substrate, and which includes a semiconductor chip, a plurality of terminals provided in rows on the bottom side of the semiconductor chip, columnar post electrodes formed of metal and bonded to first end portions of the terminals, and solder bumps formed on second ends of the post electrodes, and underfill is filled into a space formed between the wiring substrate and the semiconductor device. Here, each of the post electrodes includes first metallic portions being bonded to the terminals, and second metallic portions being bonded to the solder bumps, and the dimension of the first metallic portions in the width direction is smaller than the dimension of the second metallic portions in the width direction.

According to the above described third solving embodiment, a circuit device in which a hardening resin is filled into a space in between the semiconductor device and the wiring substrate, and it is difficult for non-underfilled portions to occur. This type of circuit device is highly effective in preventing cracks from occurring in bumps and post electrodes due to stress and thus reliability is increased.

According to at least one embodiment of the present invention, it is possible to attain a semiconductor device in which non-underfilled portions do not occur while attaining a circuit device of high reliability in preventing cracks from occurring in bumps and post electrodes due to stress.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.
Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a cross-sectional view schematically showing a circuit device according to an example embodiment of the present invention.

FIG. 2 is a view showing a part of a forming process of a semiconductor device of the circuit device of FIG. 1.

FIG. 3 is a view showing another part of the forming process of the semiconductor device of the circuit device of FIG. 1.

FIG. 4 is a view showing another part of the forming process of the semiconductor device of the circuit device of FIG. 1.

FIG. 5 is a view showing another part of the forming process of the semiconductor device of the circuit device of FIG. 1.

FIG. 6 is a view showing another part of the forming process of the semiconductor device of the circuit device of FIG. 1.

FIG. 7 is a view showing another part of the forming process of the semiconductor device of the circuit device of FIG. 1.

FIG. 8 is a view showing another part of the forming process of the semiconductor device of the circuit device of FIG. 1.

FIG. 9 is a view showing another part of the forming process of the semiconductor device of the circuit device of FIG. 1.

FIG. 10 is a view showing another part of the forming process of the semiconductor device of the circuit device of FIG. 1.

FIG. 11 is a view showing another part of the forming process of the semiconductor device of the circuit device of FIG. 1.

FIG. 12 is a view showing another part of the forming process of the semiconductor device of the circuit device of FIG. 1.

FIG. 13 is a cross-sectional view schematically showing a conventional circuit device.

FIG. 14 is a cross-sectional view schematically showing another conventional circuit device.

### DESCRIPTION OF THE PREFERRED EMBODIMENT

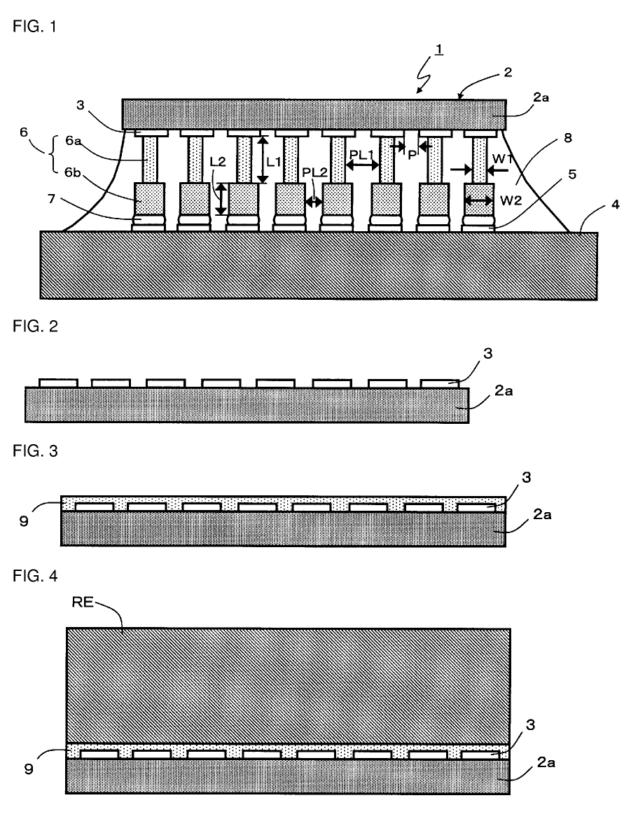

A semiconductor device and a circuit device according to an example embodiment of the present invention will now be described with reference to FIG. 1. However, the semiconductor device and circuit device are not intended to limit the present invention but illustrates an embodiment of the present invention. In the present disclosure where conditions and/or structures are not specified, the skilled artisan in the art can readily provide such conditions and/or structures, in view of the present disclosure, as a matter of routine experimentation. The numerical numbers applied in the specific embodiment may be modified by a range of at least ±50% in an embodiment, wherein the endpoints of the ranges may be included or excluded. FIG. 1 is a cross-sectional view schematically showing a portion of the circuit device according to an embodiment of the present invention that has mounted thereon the semiconductor device. A circuit device 1 has a semiconductor 2 flip-chip-mounted on a wiring substrate 4. Other wiring conductors and electronic components are omitted from description here.

The semiconductor device 2 has a semiconductor chip providing terminals 3 formed on the bottom side at a prescribed terminal pitch P, post electrodes 6 formed of columnar metal and bonded to the terminals 3 of this semiconductor chip, solder bumps 7 formed on a side of the post electrode 6 opposite the side bonded with the terminals 3. The solder bumps 7 are bonded to lands 5 formed on the wiring substrate 4. Furthermore, the space between the semiconductor device 2 and the wiring substrate 4 is filled with an underfill of epoxy resin or the like.

Each of the post electrodes 6 includes two metals different from one another, and the side bonded to the terminal 3 includes a first metallic portion 6a while the side on which the solder bump 7 is formed includes a second metallic portion 6b. Cu, Ni, Cr, Au or the like may be used as metals for the first metallic portions 6a and the second metallic portions 6b. The shape of the post electrode 6 may be cylindrical, prism-shaped, or the like.

A width direction dimension W1 of the first metallic portion 6a is formed smaller than a width direction dimension W2 of the second metallic portion 6b. The width direction dimension is the diameter if the shape is cylindrical, and the length of a side or the length of a diagonal line if the shape is a prism shape. If W1<W2 in this manner, a distance PL1 between the first metallic portions 6a of adjacent post electrodes 6 is greater than the terminal pitch of the terminals 3 of the semiconductor device 2. Because of this, even if the terminal pitch P has been narrowed in accordance with miniaturization, it is easy for underfill to enter the space from the portion where the first metallic portion 6a is formed. As a result, it becomes possible to fill the space in between the semiconductor device 2 and the wiring substrate 4 in such a manner that portions not filled with underfill 8 do not occur.

Also, it is preferable for a length L1 of the first metallic portions 6a to be formed larger than a length L2 of the second metallic portions 6b. Since the distance PL2 between the second metallic portions 6b is smaller than the distance PL1 between the first metallic portions 6a, it is preferable that the second metallic portions 6b be as small as possible. However, the second metallic portions 6b have a role in ensuring bonding with the wiring substrate 4, and it is necessary to provide a bonding area for the purpose of attaining a sufficient bonding strength. Therefore, by making L1>L2 it is possible to attain both ease of underfill entry as well as sufficient bonding strength with the wiring substrate 4.

In embodiments, the measurements may fall within the following ranges: L1=15 μm to 80 μm; L2=2 μm to 30 μm; W1=15 μm to 85 μm; W2=25 μm to 95 μm; P=30 μm to 100 μm; PL1=15 μm to 85 μm; PL2=5 μm to 75 μm; L1/L2=1 to 4; W1/W2=0.16 to 1; PL1/PL2=1 to 17.

Next, a process of forming the semiconductor device of the embodiment of the present invention will be described with reference to FIGS. 2 to 12. The process is not intended to limit the embodiment or the present invention but illustrates an embodiment of the present invention. Description will be given using, as an example, the semiconductor device 2 having a semiconductor chip 2a in which the terminals 3 are constituted by Al metal and provided at a terminal pitch of 60 μm, and the post electrodes 6 in which the first metallic portions 6a are Cu cylinders of W1=20 μm diameter, L1=40μm, and the second metallic portions 6b are Ni cylinders of W2=40 μm diameter, L2=20 μm. This example illustrates an embodiment of the present invention and is not intended to limit the present invention.

First, a semiconductor chip 2a is prepared. As shown in FIG. 2, the chip 2a is prepared so that the portion on which the terminals 3 are formed, that is, the bottom side, faces up. Next, as shown in FIG. 3, a seed layer 9 is formed on the semiconductor chip 2a using a sputtering or deposition technique to cover the terminal 3. This seed layer 9 is formed of a metal, or an alloy, that is basically the same as the metal constituting the first metallic portions 6a of the post electrodes 6 that will be formed later. Here, the first metallic portions 6a include Cu, therefore Cu is used for the seed layer 9.

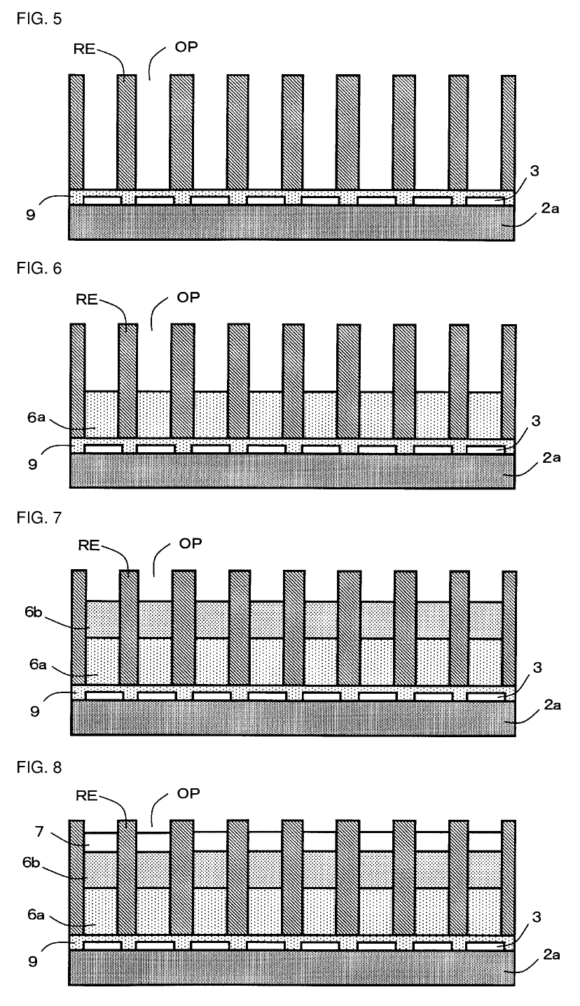

Next, as shown in FIG. 4, a plate resist film RE is formed on the seed layer 9 by way of coating. A photoresist is used as this plate resist film. Light is irradiated onto this plate resist film RE through a photo mask (not shown) producing a pattern corresponding to the terminals 3 on the semiconductor device 2, then development is performed, and, as shown in FIG. 5, opening portions OP are formed at locations corresponding to the terminals 3 on the semiconductor chip 2a. A positive type photoresist in which portions irradiated by light are removed, or negative type photoresist in which portions irradiated by light are insolubilized, can be used as the photoresist. In a case of using the positive type photoresist, a photo mask is used that allows light to pass through in the shape of the pattern of the opening portions OP, and in a case of using a negative type photoresist, a photo mask is used that blocks light in the shape of the pattern of the opening portions OP. The opening portions OP are formed so that the size of the opening portions OP are approximately the same as the width direction dimension W2 of the second metallic portions 6b, that is, 40 μm in diameter.

Next, as shown in FIG. 6, the first metallic portions 6a are formed by Cu electroplating. An electric current flows through the seed layer 9, and thereby Cu is deposited on the seed layer 9 inside the opening portions OP. The length L1 of the first metallic portions 6a can be adjusted by changing the electric current density or the energization time period used in the electrolytic Cu plating. Here, L1 is adjusted to 40 μm. Next, as shown in FIG. 7, the second metallic portions 6b are formed by Ni electroplating. An electric current flows through the seed layer 9 at this time as well, and thereby Ni is deposited on the seed layer 9 within the opening portions OP. The length L2 of the first metallic portions 6b can also be adjusted by changing the electric current density or the energization time period of the electrolytic Cu plating. Here, L2 is adjusted to 20 μm. Next, as shown in FIG. 8, a solder layer is formed to latter become the solder bumps 7, by solder electroplating. Tin alloys such as Sn—Ag, Sn—Cu, Sn—Pb, Sn—Zn or the like may be used as the material of the solder bumps 7. The solder layer is formed inside the opening portions OP, and therefore at this stage is formed of 40 μm diameter cylinders approximately the same as the post electrodes 6.

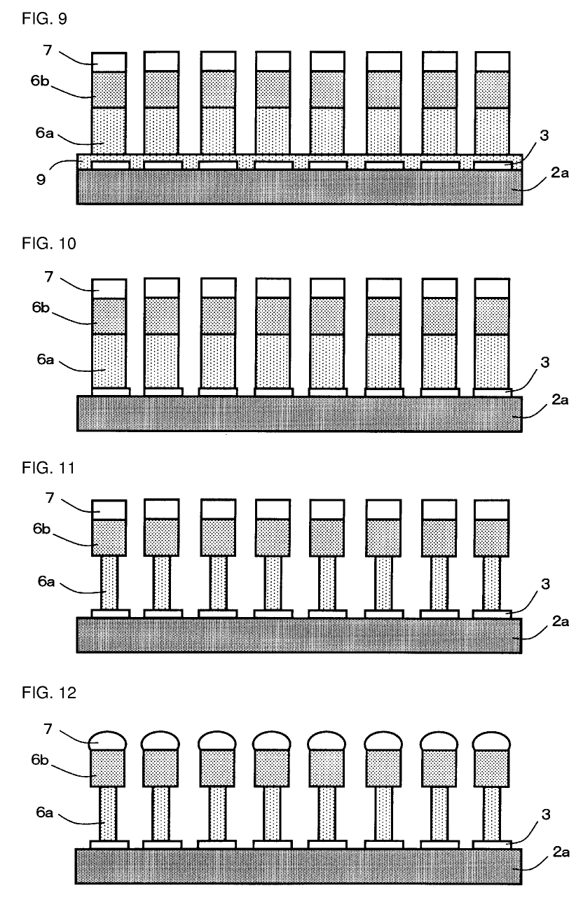

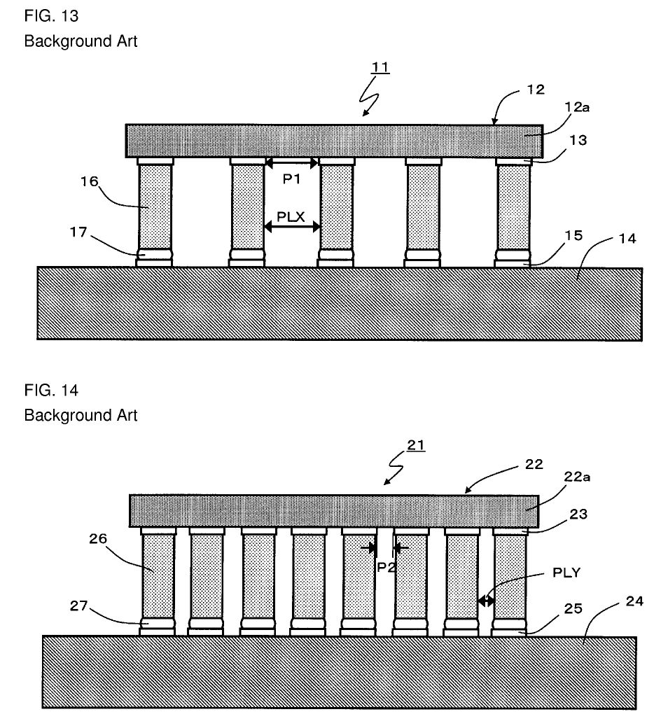

Next, as shown in FIG. 9, the plate resist film RE is removed. In this way, the 40 μm diameter metal columns formed of the first metallic portions 6a, the second metallic portions 6b, and the solder layer at the locations corresponding to the terminals 3 on the semiconductor chip 2a on the seed layer 9 are realized. Next, as shown in FIG. 10, the seed layer 9 is removed by etching. A liquid etchant that can selectively etch Cu is used. In this way, the metal columns that include the post electrodes 6 and the solder bumps 7 are formed on the terminals 3.

Next, as shown in FIG. 11, the first metallic portions 6a are etched so that the width direction dimension W1 of the first metallic portions 6a becomes smaller than the width direction dimension W2 of the second metallic portions 6b. The metal constituting the first metallic portions 6a is approximately the same as the metal constituting the seed layer 9, and therefore it is possible to use the same liquid etchant. In this case, it is possible to carry out etching of the first metallic portions 6a in continuation from the process step of removing the seed layer 9, or it is possible to switch to a different concentration of the same liquid etchantand and then to carry out etching of the first metallic portions 6a. The dimension in the width direction can be adjusted by changing the treatment time used in the etching. Here, the diameter of the first metallic portions 6a is set to 20 μm. In this way, the post electrodes 6 of this embodiment are formed.

Next, the semiconductor device 2 is inserted into a reflow oven to cause the solder layer to flow, and, as shown in FIG. 12, the solder bumps 7 are formed on the end portions of the second metallic portions 6b. In this way, the semiconductor device 2 of this embodiment can be obtained.

Though the semiconductor device and circuit device according to the specific embodiments of the present invention have been described above, the terminal pitch of the semiconductor chip 2a, the diameter of the post electrodes 6, and the like, are arbitrary and may be changed appropriately. The metallic materials and process conditions may also be changed appropriately, and the liquid etchants and the like that are used may also be selected appropriately.

The present application claims priority to Japanese Patent Application No. 2007-247032, filed Sep. 25, 2007, the disclosure of which is incorporated herein by reference in its entirety.

It will be understood by those of skill in the art that numerous and various modifications can be made without departing from the spirit of the present invention. Therefore, it should be clearly understood that the forms of the present invention are illustrative only and are not intended to limit the scope of the present invention.

What is claimed is:

1. A semiconductor device comprising:
a semiconductor chip;
a plurality of terminals provided in rows on a bottom side of said semiconductor chip;
a plurality of post electrodes formed of columnar metal and each having first and second ends, wherein the first ends of the post electrodes are bonded to the respective terminals; and
a plurality of solder bumps formed on the respective second ends of the post electrodes,
wherein each post electrode is constituted by a first metallic portion including the first end bonded to the terminal, and a second metallic portion including the second end bonded to the solder bump, and a dimension of said first metallic portion in a width direction is smaller than a dimension of said second metallic portion in a width direction.

2. The semiconductor device according to claim 1, wherein a length of said first metallic portions is larger than a length of said second metallic portions.

3. The semiconductor device according to claim 1, wherein the first and second metallic portions are cylindrical and made of different metals.

4. The semiconductor device according to claim 3, wherein the first metallic portion is Cu, and the second metallic portion is Ni.

5. A circuit device comprising:
(i) a wiring substrate;
(ii) a semiconductor device flip-chip-mounted on the wiring substrate, said semiconductor device comprising:
a semiconductor chip, and
a plurality of terminals provided in rows on a bottom side of said semiconductor chip;
a plurality of post electrodes formed of columnar metal and each having first and second ends, wherein the first ends of the post electrodes are bonded to the respective terminals; and
a plurality of solder bumps formed on the respective second ends of the post electrodes,
wherein each post electrode is constituted by a first metallic portion including the first end bonded to the terminal, and a second metallic portion including the second end bonded to the solder bumps, and a dimension of said first metallic portion in a width direction is smaller than a dimension of said second metallic portion in a width direction; and
(iii) underfill filled into a space formed in between the wiring substrate and the semiconductor device.

6. The circuit device according to claim 5, wherein a length of said first metallic portions is larger than a length of said second metallic portions.

7. The circuit device according to claim 5, wherein the first and second metallic portions are column-shaped and made of different metals.

8. The circuit device according to claim 5, wherein the space formed in between the wiring substrate and the semiconductor device has substantially or nearly no unfilled underfill portion.
